(19) United States
(12) Patent Application Publication
(10) Pub. No.: US 2006/0006554 A1
(43) Pub. Date: Jan. 12, 2006

(54) Vertical structure semiconductor devices with improved light output

(76) Inventors: Myung Cheol Yoo, Pleasanton, CA (US); Dong Woo Kim, Dublin, CA (US); Geun Young Yeom, Dublin, CA (US)

Correspondence Address: IPSG, P.C., P.O. BOX 700640, SAN JOSE, CA, 95170-0640, US

(21) Appl. No.: 11/165,110

(22) Filed: Jun. 22, 2005

Related U.S. Application Data
(60) Provisional application No. 60/582,098, filed on Jun. 22, 2004.

(51) Int. Cl. H01L 29/739

(52) U.S. Cl. 257/900

(57) ABSTRACT

The invention provides a reliable technique to fabricate a new vertical structure compound semiconductor devices with highly improved light output. An exemplary embodiment of a method of fabricating light emitting semiconductor devices comprising the steps of forming a light emitting layer, and forming an undulated surface over light emitting layer to improve light output. In one embodiment, the method further comprises the step of forming a lens over the undulated surface of each of the semiconductor devices. In one embodiment, the method of claim further comprises the steps of forming a contact pad over the semiconductor structure to contact with the light emitting layer, and packaging each of the semiconductor devices in a package including an upper lead frame and lower lead frame. Advantages of the invention include an improved technique for fabricating semiconductor devices with great yield, reliability and light output.

### RELATED APPLICATIONS

This application claims priority to U.S. Prov. No. 60/582,098 filed Jun. 22, 2004, incorporated herein by reference.

### FIELD

The invention is related to fabricate GaN-based vertical structure semiconductor devices having a top and bottom contact structure and a method to fabricate the vertical structure devices.

### BACKGROUND

FIG. 1 depicts a conventional Gallium Nitride (GaN)-based semiconductor device 100 fabricated on an insulating sapphire substrate 114. This device can be for applications such as a Light Emitting Diode (LED), Laser Diode (LD), Hetero-junction Bipolar Transistor (HBT) and High Electron Mobility Transistor (HEMT). During the conventional process, the device is formed on a sapphire substrate and both electrical contacts are formed on the top side of the device. A p-contact 102 is formed on the top and mesa etching is employed to remove material to form an n-metal contact 116. The result is called a lateral structure device and tends to exhibit several problems including weak resistance to electrostatic discharge (ESD) and heat dissipation. Both of these problems limit the device yield and useful life time. In addition, the sapphire material is very hard, which creates difficulty in wafer grinding and polishing, and device separation. Device fabrication yield is dependent on post fabrication processes including lapping, polishing, and die separation.

FIG. 2 depicts a second conventional technique that has become useful in building vertical structure GaN-based compound semiconductors 200. A laser lift-off (LLO) process is used to remove the sapphire substrate from the GaN epitaxial layer by applying an excimer laser having wavelength transparent to sapphire, typically in the UV range. The devices are then fabricated by substituting the insulating sapphire substrate with a conductive or semi-conductive second substrate 218 to build vertical structure devices. These processes typically employ wafer-bonding techniques for permanent bonding to the second substrate after or before removing sapphire substrate by laser lift-off.

However, there is still lacking a large scale laser lift-off process for the mass production of VLEDs (Vertical LED). One reason is the difficulty in large area laser lift-off due to non-uniformity of bonding adhesive layer 216 between support wafer 218 and the epitaxial layer 214 and the permanent second substrate 218 since the epitaxial layer surface is not flat over entire wafer surface after laser lift-off. Another problem associated with this wafer bonding technique is the degradation of metal contacts due to high temperature and high pressure during eutectic metal bonding process. Furthermore, substrates such as Si or GaAs used for the permanent wafer bonding are not optimal substrates in terms of heat dissipation compared to a Cu-based metal substrate. These problems reduce the final yield and do not provide a satisfactory solution to mass production of commercially viable devices.

FIGS. 3A-B depicts a structure 300 intended to overcome the wafer bonding problems and fabricate VLEDs. Instead of using a wafer bonding method, the fabrication of device 300 includes attaching a metal support 318 to the device. However, the yield is known to be low due to de-lamination of the bonding layer during the laser lift-off process. If the bonding is not secure against the high-energy laser shock wave, the GaN epitaxial layers may buckle or crack after laser lift-off, and then it is difficult to perform post laser lift-off processes, such as wafer cleaning, device fabrication, de-bonding and device separation. Consequently, final device process yield is low.

Another problem of vertical devices based on the technique shown in FIGS. 3A-B is poor device performance. Since a sand blast is used on the sapphire substrate to improve uniform laser beam energy distribution, the GaN surface after laser lift-off is typically rough, which results in less light output than if it were a flat, smooth surface. In addition, the metal reflective layer formed on the n-GaN layer is not as high as non-metallic reflector material, such as ITO.

Yet another limitation of vertical devices based on the technique shown in FIGS. 3A-B is the location of the p-contact 302 in the center of the device, between transparent contacts 304a-304b. This position is preferred for conventional wire bonding contact, but requires that a wire be bonded to the center of the device.

Due to these limitations of conventional techniques, a new technique is needed that can improve device performance and fabrication yield in high volume production of GaN-based semiconductor devices.

### SUMMARY

The invention provides a reliable technique to fabricate a new vertical structure compound semiconductor devices with highly improved light output.

An exemplary embodiment of a method of fabricating light emitting semiconductor devices comprising the steps of forming a light emitting layer, and forming an undulated surface over light emitting layer to improve light output beam profile. In the invention, the improvement in beam profile refers to the chip-level angle of light output.

In one embodiment, the step of forming an undulated surface includes the step of forming a plurality of substantially micro-lenses. This process includes the steps of depositing a mask over the semiconductor structure, removing a portion of the mask resulting in a plurality of substantially circular masks on the surface of the semiconductor structure, etching the semiconductor structure, and removing residual mask.

In one embodiment, the invention comprises the steps of forming a light emitting layer, and forming a macro-lens over the surface of each of the semiconductor devices to improve light output beam profile. In one aspect, the macro-lens is formed over the undulated surface of the semiconductor devices. In another aspect, the semiconductor devices do not have undulated surfaces.

In one embodiment, the method comprises the steps of forming a contact pad over the semiconductor structure to contact with the light emitting layer, and packaging each of the semiconductor devices in a package including an upper lead frame and lower lead frame, wherein contact with the semiconductor device is between the upper lead frame and lower lead frame. In one aspect, contact is formed by one or more of pressure, heat, and vibration between the upper lead frame and lower lead frame.

Advantages of the invention include an improved technique for fabricating semiconductor devices with great yield, reliability and light output.

### DRAWINGS

The invention is described with reference to the following figures.

FIG. 1 depicts a lateral structure GaN-based LED with two metal contacts are formed on the topside of device, according to the prior art.

FIG. 2 depicts a vertical structure GaN-based LED where a GaN thin membrane is bonded to a conductive or semi-conductive second substrate, according to the prior art.

FIGS. 3A-B depict a vertical structure GaN-based LED where a thick metal layer is attached to a GaN thin membrane after removing original sapphire substrate, according to the prior art.

FIG. 4 is a flowchart showing a method of fabricating a semiconductor device according to an embodiment of the invention.

FIG. 5 depicts a light emitting semiconductor device including a GaN LED wafer attached to a perforated support wafer carrier using conductive adhesive glue prior to laser lift-off, according to an embodiment of the invention.

FIG. 6 depicts an eximer laser beam applied through the sapphire substrate using a diffusing media to obtain uniform laser beam energy distribution during laser lift-off process, according to an embodiment of the invention.

FIG. 7 depicts the sapphire substrate removal and Ga drop cleaning after laser lift-off, according to an embodiment of the invention.

FIG. 8 depicts GaN/AlGaN buffer layer removal by etching according to an embodiment of the invention.

FIG. 9 depicts an n-type ITO transparent contact formation on top of the GaN LED layer, according to an embodiment of the invention.

FIG. 10 depicts a protective SiO₂ passivation layer deposition, according to an embodiment of the invention.

FIGS. 11A-B depict support wafer carrier removal and final device structure, according to an embodiment of the invention.

FIG. 12 depicts device separation by dicing or laser scribing, according to an embodiment of the invention.

FIGS. 13A-F depict a method of forming micro-lenses in the n-GaN, according to an embodiment of the invention.

FIG. 14 is a flowchart showing steps for performing the micro-lens formation, according to an embodiment of the invention.

FIGS. 15A-B depict exemplary size and placement of the micro-lenses, according to an embodiment of the invention.

FIGS. 16A-F depict a method of forming macro-lenses, according to an embodiment of the invention.

FIG. 17 is a flowchart showing steps for performing the-macro-lens formation, according to an embodiment of the invention.

FIGS. 18A-C depict exemplary beam profiles for backlighting LCD displays, according to embodiments of the invention.

FIGS. 19A-B depict a method of packaging semiconductor devices, according to an embodiment of the invention.

FIG. 20 is a flowchart showing steps for performing the packaging, according to an embodiment of the invention.

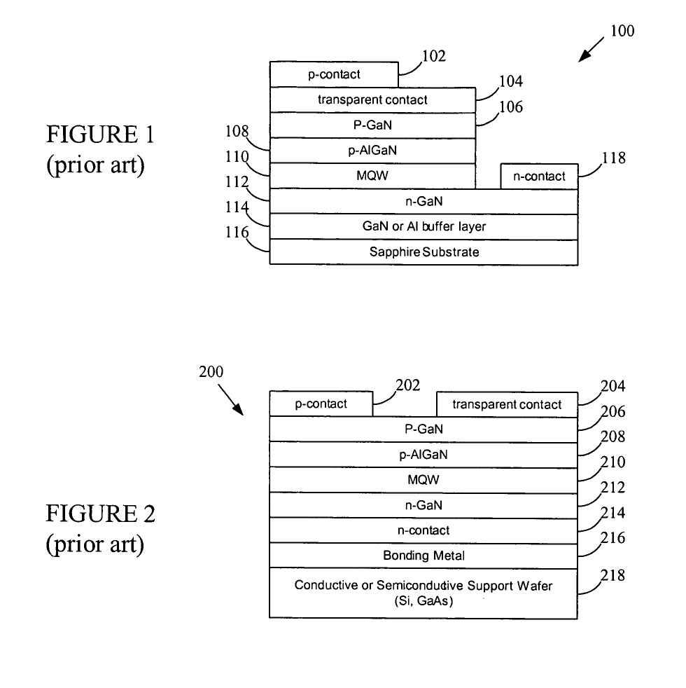

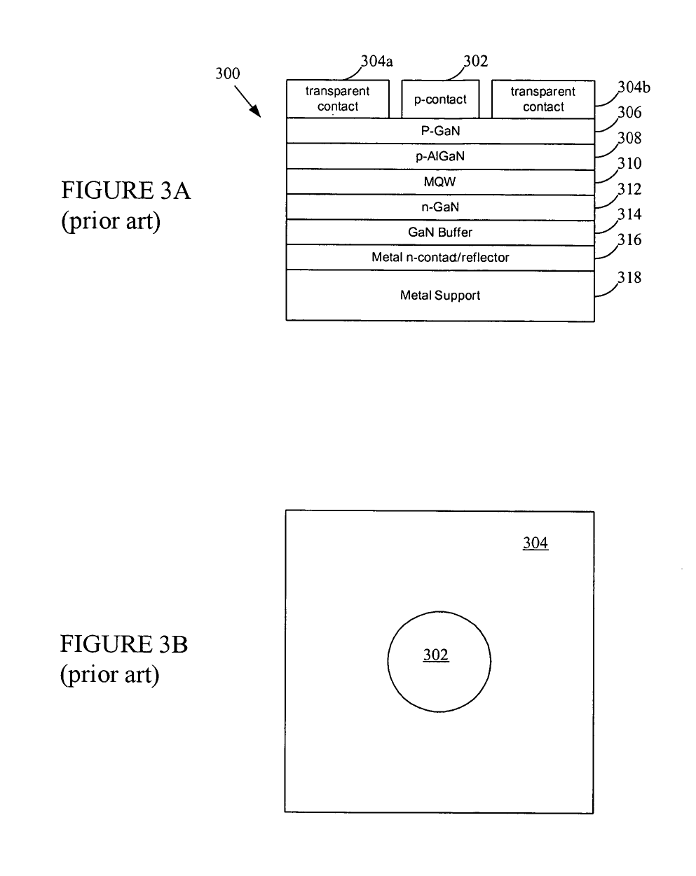

### DETAILED DESCRIPTION

The invention is described with reference to specific device structure and embodiments. Those skilled in the art will recognize that the description is for illustration and to provide the best mode of practicing the invention. The invention includes a number of forming and depositing steps to fabricate a semiconductor device according to the invention. The disclosure refers to depositing materials over or on other materials, which is described and depicted as representing an arbitrary frame of reference and is intended to describe and cover techniques that deposit materials over-top, on, or below other materials as explained and understood by those of skill in the art and in conjunction with the description. For example, portions of the disclosure describes semiconductor layers constructed from above and other portions describes semiconductor layers constructed from below, while in both cases, a new layer deposited over an existing layer means that it is deposited above or below the existing layer as described and illustrated. Numerous process parameters are provided herein to provide the best mode, while variations of the parameters may also result in the process, structure, and advantages as described herein. Variations of the invention are anticipated and encompassed by the claims.

A. Device Structure and Fabrication

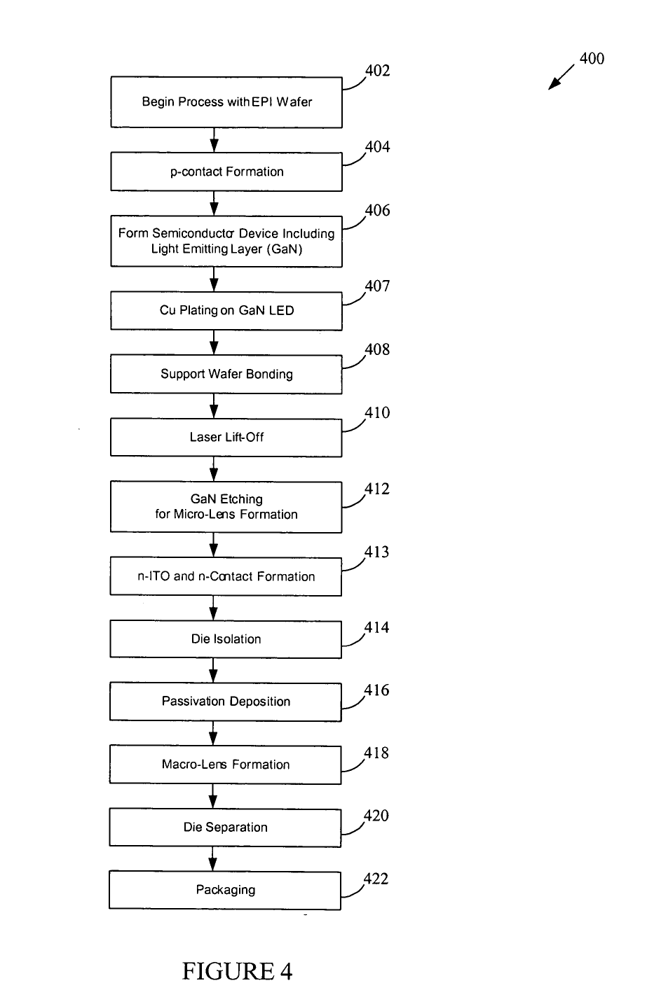

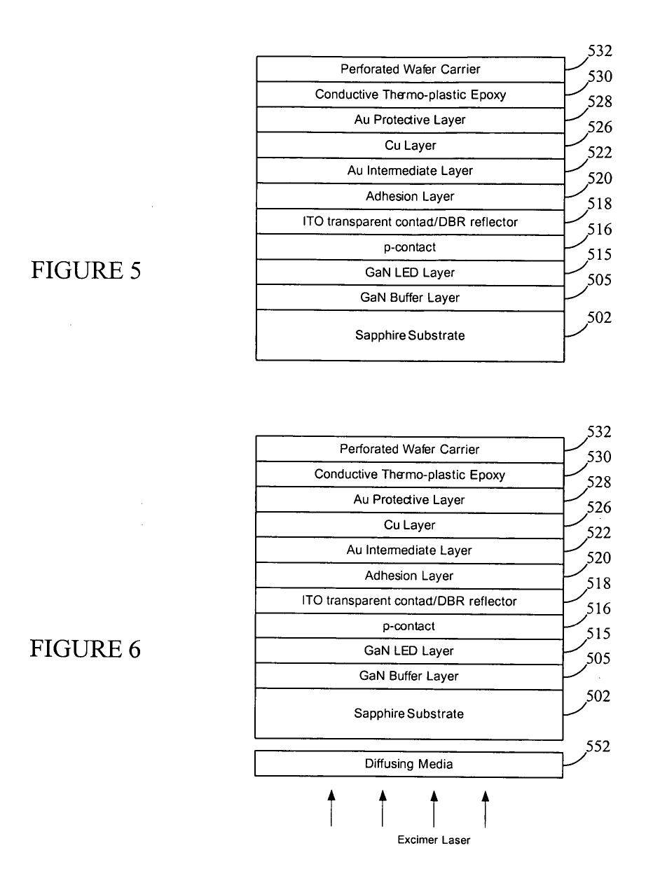

FIG. 4 is a flowchart 400 showing a method of fabricating a semiconductor device according to an embodiment of the invention. The steps depicted in the flowchart are for the purpose of demonstrating the exemplary embodiments and structures and the invention includes portions of modifications of the method and resulting structures as set forth herein. Step 402 begins the exemplary process with an epitaxial wafer. Step 404 involves p-contact formation, step 408 involves a light emitting device layer formation, for example GaN LED. Step 408 involves wafer carrier bonding. The initial semiconductor device is depicted in FIG. 5. Reference number 500 is intended to refer to the semiconductor that may result in one or more devices. In the event of many devices, the references are provided with alphabetic suffixes such as 500a, 500b, 500c and so on. The steps are described with reference to the semiconductor structure fabrication and packaging depicted in FIGS. 5-12 and other figures as described.

As shown in FIG. 5, Sapphire/GaN/Cu/Au wafers are bonded to a perforated wafer carrier 532 using a conductive thermo-plastic epoxy 530. The perforated wafer carrier is made out of stainless steel with holes. The reason to use the metal wafer carrier is to provide the electrical and heat conduction during the inductively coupled plasma (ICP) etching, wafer probing and die isolation. By using a metal wafer carrier, there is less need to remove wafer from the carrier for post fabrication processing. In addition, the perforated wafer carrier provides bubble-free wafer bonding since air bubbles can escape easily through the holes during the bonding process. It also provides easy de-bonding between the Sapphire/GaN/Cu/Au wafer and the wafer carrier since a solvent can penetrate through the holes during de-bonding process. By using the perforated wafer carrier, the entire process is easy, reliable and simple which leads to high fabrication yield for the fabrication of the vertical devices. The exemplary thickness of wafer carrier is 1/16 inches and the diameter is 2.5 inches. The exemplary total number of holes is 21 and the through hole diameter is 20/1000 inches. The exemplary wafer carrier surface is electro-polished to make mirror like flat surface for the uniform bonding with the adhesive.

Silver-based conductive adhesives are used to bond the Sapphire/GaN/Cu/Au and the perforated wafer carrier. The conductive adhesive is used to provide the good electrical and thermal conduction for the wafer probing and die isolation etching process. The thermo-plastic epoxy has good adhesion strength and good heat resistance. Another advantage of the thermo-plastic epoxy is that it can be dissolved in the solvent, such as acetone, very easily, which is useful for the de-bonding process.

In the invention, a sheet-type thermo-plastic epoxy is employed because the film thickness of the sheet type epoxy is more uniform than that of liquid-base adhesives. The liquid-base adhesives often result in uneven thickness uniformity and bubble formation in the previous bonding process experiences since the spin coating of the liquid-base adhesives generally leads to thicker film formation in the wafer fringe side than that of center area of the wafer. This is a common phenomena for the liquid-base adhesives to obtain thick adhesive layers by multiple spinning. For the bonding of thermo-plastic epoxy, 127 μm-thick sheet-type thermo-plastic epoxy is sandwiched in between thick metal support and perforated wafer carrier. The pressure is set to about 10˜15 psi and the temperature is maintained below 200° C. in the hot iso-static press. At these conditions, the bonding time is less than 1 minute. This short bonding time has a definite advantage over to that of liquid-base adhesives, which may require more than 6 hour curing time for the complete curing of the adhesive. The short bonding process time also greatly enhance the productivity of the vertical device fabrication.

Referring to FIG. 6, a 248 nm KrF ultra violet (UV) excimer laser (pulse duration of 38 ns) is used for laser lift-off. The reason for choosing this wavelength is that the laser should beneficially transmit through the sapphire but be absorbed in the GaN epitaxial layer in order to decompose the GaN into metallic Ga and gaseous nitrogen (N₂) at the GaN/sapphire interface. The laser beam size is chosen as a 7 mm×7 mm square beam and has beam power density between 600˜1,200 mJ/cm². It is also suggested that the laser beam energy density is dependent on the surface roughness of the sapphire substrate surface. In order to obtain smooth GaN surface after laser lift-off, the beam energy higher than 800 mJ/cm² was used for the mechanically polished sapphire substrate 10˜20 angstrom in RMS value.

Surface roughness of the sapphire substrate is an important process parameter for obtaining a smooth GaN surface after laser lift-off. If un-polished sapphire surface is used during laser lift-off, the GaN surface is rough, which results in poor light output of the LED device due to poor reflectivity of the rough surface after forming a final device. However, if a polished surface is used, a smooth GaN surface can be obtained, hence higher light output can be obtained. However, since the laser beam is localized on the polished sapphire surface, the area irradiated with the higher laser beam power may result in cracking on the GaN surface compared to the area with less laser beam energy. Therefore, it is important to choose an optimal surface roughness of sapphire wafer in order to obtain a high yield laser lift-off process and a high device performance at the same time. According to conventional techniques, sand blasting is commonly used to obtain uniform laser beam distribution on the polished sapphire surface, however, sand blasting is unreliable and unrepeatable to obtain the identical surface roughness consistently. In the invention, a diffusing media 552 constructed from materials transparent to the 248 nm UV laser is placed in between laser beam and sapphire substrate to obtain uniform laser beam energy distribution on the sapphire surface, hence to enhance the laser lift-off process yield. The rms (root mean square) surface roughness of the diffusing media is set up less than 30 μm and sapphire was used for the diffuser.

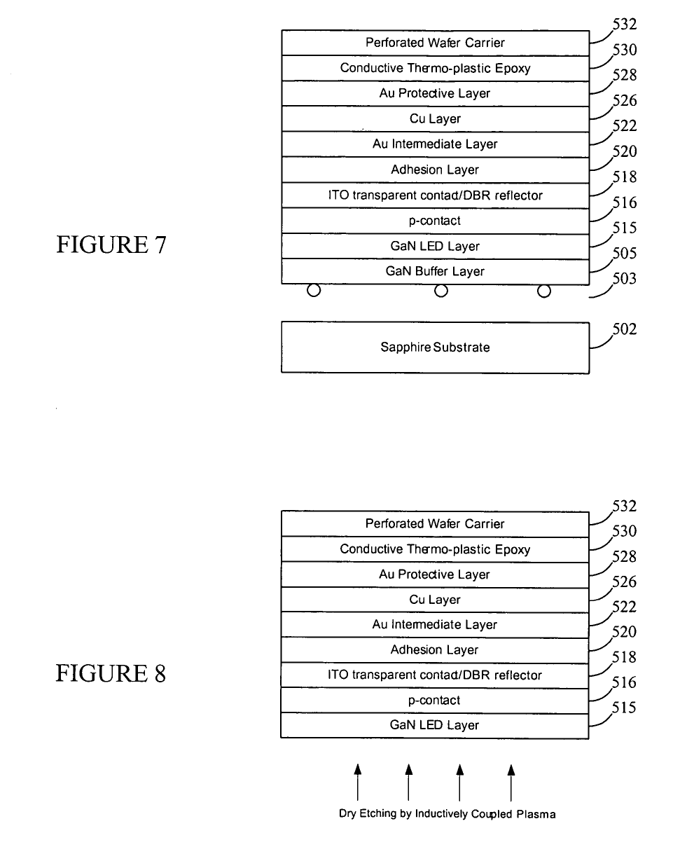

Referring to FIG. 7, after laser lift-off, excess Ga drops 503 result from GaN decomposition during laser lift-off, and is cleaned with an HCl solution (HCl: H₂O=1:1, at room temperature) or boiled using HCl vapor for 30 seconds. Since the Ga melts at room temperature, Ga is formed in a liquid state during the laser lift-off.

Referring to FIG. 8, in order to expose n-type GaN epitaxial layer, the buffer layer 505 (e.g. GaN or AlN and AlGaN buffer layers) are removed by dry etching; beneficially using inductively coupled reactive ion etching (ICPRIE). The invention performs the etching in order to form an undulated surface over the light emitting layer to disperse light output. In one aspect, the invention permits the GaN droplets to solidify on the GaN surface in order to assist in creating the undulated layer. In another aspect, the undulated layer is formed using photoresist and etching as described below. In either event, the undulated surface creates a series of micolenses that serve to disperse the light output over a broad area. Note that the undulated surface can be constructed by concave and/or convex structures to improve light output.

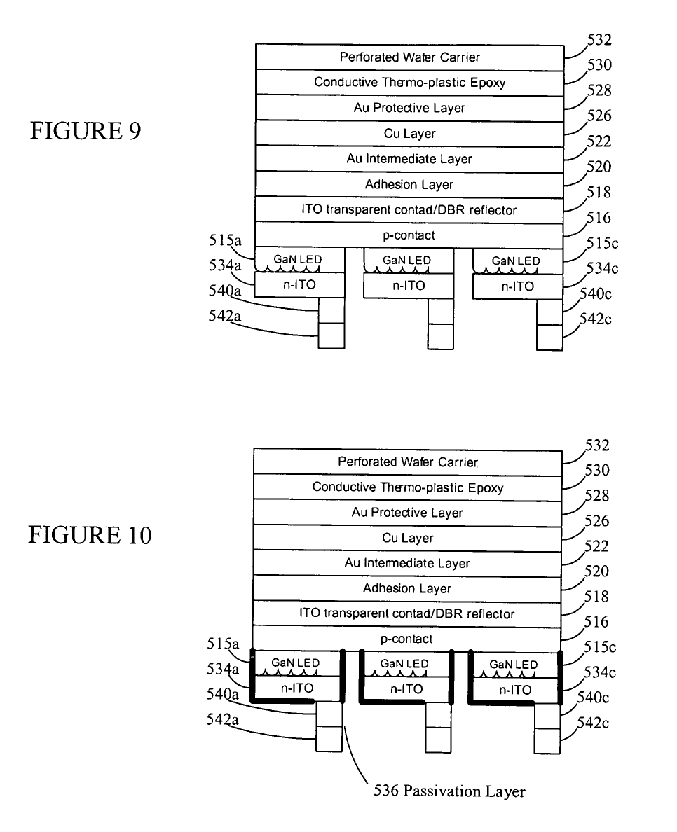

Referring to FIG. 9, in order to improve the current spreading of the vertical device, an n-type ITO transparent contact 534 is formed on the n-GaN LED surface 515. This figure depicts the undulated GaN layer interface with the ITO layer. ITO composition is 10 wt % SnO₂/90 wt % In₂O₃, and a layer of about 75˜200 nm-thick ITO film is deposited using an electron beam evaporator or sputtering system at room temperature. Annealing is carried out after the ITO film deposition in a tube furnace with N₂ ambient for 5 minutes. The annealing temperatures are varied in between 300° C. to 500° C. The minimum resistivity of the ITO film is about low 10⁻⁴ Ωcm at 350° C. of annealing temperature in N₂ ambient. The transmittances at 460 nm are over 85% at the annealing temperature of above 350° C.

After the ITO transparent contact formation, an n-contact 540 is formed on the n-ITO surface, comprising of Ti and Al. Since multiple contacts are formed, they are referenced as 540a, 540b, 540c and so forth. The thickness of the n-contact metal is 5 nm for Ti, and 200 nm for Al, respectively. In order to make a good adhesion between the n-contact metal layer and a pad metal 542, 20 nm of Cr is deposited on top of the Al as an adhesion layer. For the pad metal deposition, 500 nm gold is deposited on top of the Cr consecutively in an electron beam evaporation chamber without breaking vacuum. In order to form an ohmic contact, the n-contact metal is annealed in the furnace at 250° C. for 10 minute in an N₂ ambient atmosphere.

After cleaning the GaN surface, individual devices are isolated by a MICP (magnetized inductively coupled plasma) dry etching technique. The MICP can accelerate the etch rate compared with the other dry etching methods. This is useful to prevent the photo-resist mask burning during the etch process. The MICP usually provides about twice the etch rate compared to conventional ICP. Fast etch rate is recommended for the processing of the vertical devices having metal support since the metal substrate can be attacked by chemicals designed for removing metal or oxide masks. Therefore, in order to use the photo-resist mask for the die isolation etching, fast etching technique is suggested. The exemplary isolation trench dimension is 30 μm wide and 3.5 μm deep the etch depth is dependent upon epitaxial wafer thickness. The die isolation is also carried out either by mechanical dicing or laser scribing.

Referring to FIG. 10, a passivation layer 536 is deposited on exposed portions of the devices. In order to protect device from the external hazardous environment and to increase the light output by modulating reflective index between the passivation layer and the GaN, the vertical device is passivated with a SiO₂ thin film 536. The film is deposited with PECVD (Plasma Assisted Chemical Vapor Deposition) at less than 250° C. The film thickness is maintained at 80 nm for the optimal reflective index.

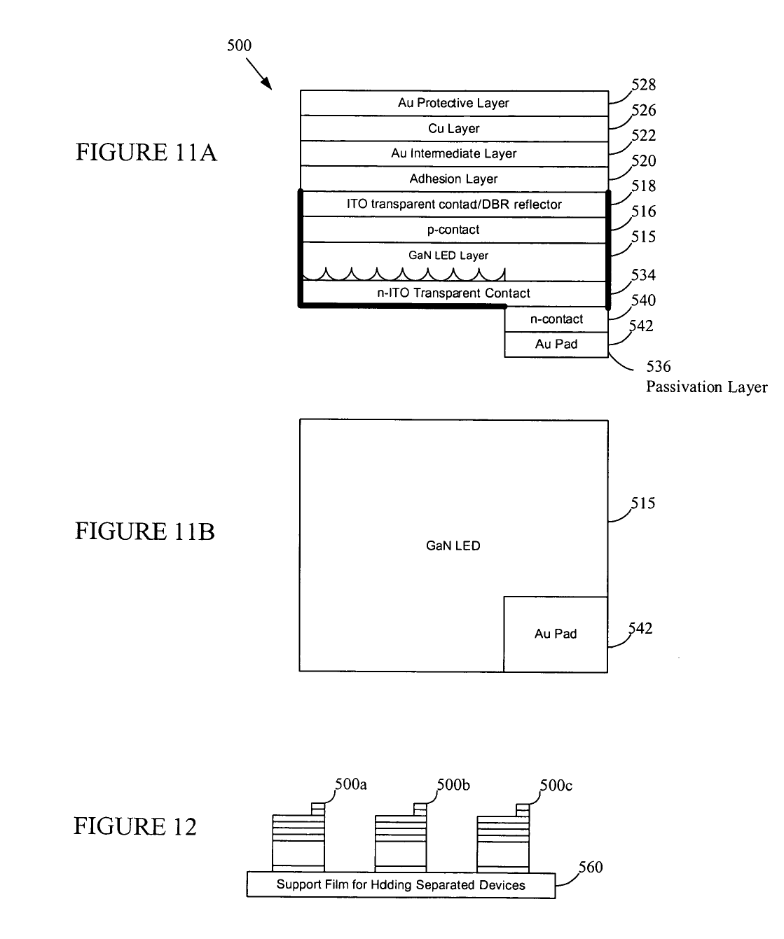

Referring to FIG. 11A, after the passivation deposition, the perforated support wafer carrier is removed from the GaN/metal support wafer using solvent. FIG. 11B is a top view of the device showing the Au pad position. The de-bonding process includes soaking of the GaN/metal wafer in acetone for 0.5˜1 hour to dissolve the conductive adhesive layer from the perforated support wafer carrier. The separated GaN/metal wafers are further soaked and cleaned with isopropanol in an ultrasonic cleaner. The GaN device surface is further cleaned with DI water using rinse and dryer.

Referring to FIG. 12, in order to separate individual device from the wafer, the devices are diced out by laser scribing using an Nd;YAG laser. The wafer having vertical devices with a metal substrate is placed on porous vacuum chuck. The Nd;YAG laser is focused on the 30 μm-wide trenches formed with MICP. After laser scribing is completed, the separated chips are transferred to tacky wafer grip tape. Prior to the pick and place process, the separated chips are flipped from the first wafer grip to another wafer grip 560, so that the GaN surface is located on top of the device.

The invention further includes advanced techniques for forming an undulated surface over the light emitting layer, forming a macro-lens over the semiconductor devices, and packaging the semiconductor devices. These techniques can be used separately or together, and other substitute techniques can be used in the invention.

B. Micro-Lens Formation

As described above, one technique for forming undulations is to use GaN droplets created after laser lift-off process to assist in the formation of the undulations. The desired result is a series of substantially convex lenses. Other techniques include masking predefined areas and etching the GaN surface by dry etching, such as ICPRIE (Inductively Coupled Plasma Reactive Ion Etching) to create lenses in predefined curvature, size, and locations. Note that the micro-lenses forming the undulated surface can be constructed by concave and/or convex structures to improve light output.

In one aspect, micro-lenses are formed on n-type GaN surface at a lens height of higher than 2 μm. In practice, the p-GaN thickness is typically thinner than 0.5 ∥m due to epitaxial layer quality, which makes it difficult to form 2 μm high lens structure. Consequently, the epitaxial layer is preferably designed to have an n-GaN thickness greater than 2 μm.

Prior to forming lenses on the n-GaN surface, remaining GaN and AlGaN buffer layers are etched away to expose the n-GaN surface. Furthermore, n-GaN surface smoothening is performed using ICPRIE. The reason for the surface smoothening is to maintain a flat n-GaN surface to form low n-type metal contacts. The surface smoothening etching is performed using 100% BCl₃ gas in the ICPRIE. Usually forming a metal contact on the rough or undulated surface results in high contact characteristics compared to the metal contact formed on a flat surface.

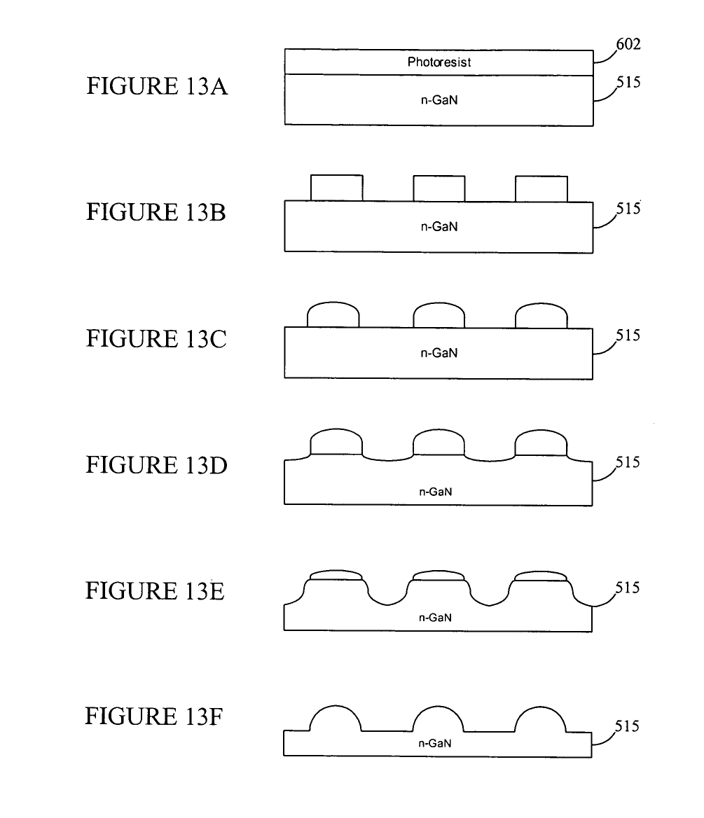

FIGS. 13A-F depict a method of forming micro-lenses in the n-GaN, according to an embodiment of the invention. FIG. 13A depicts the light emitting layer 515 (n-GaN) with a photoresist mask layer 602 deposited over the semiconductor structure. FIG. 13B depicts removing a portion of the mask resulting in a plurality of substantially circular masks on the surface of the semiconductor structure. FIG. 13C depicts photoresist mask reflow to form convex, and preferably, hemispherical shaped lenses. This is done by baking photoresist mask at around 110 Celsius for 30 seconds. FIGS. 13 D-E depict etching the semiconductor structure. ICPRIE etching is performed in such a way to obtain highly anisotropic etching characteristics. This can be done with high concentration (>90%) of Cl₂ gas in the mixture of Cl₂ and BCl₃ gases. In order to obtain the hemispherical lens shape morphology, the bias voltage is also maintained higher compare to the normal etching conditions. FIG. 13F depicts removing residual mask resulting in a series of substantially convex lenses.

In one aspect, FIG. 13B is a patterning step where the photoresist is patterned in a series of circular masks approximately 4 μm in diameter and at approximately 8 μm patterns. FIG. 13C depicts where the photoresist is baked to fix the pattern. FIG. 13D depicts an initial stage of ICP etching with Cl₂ and Ar. FIG. 13E depicts a final stage of ICP etching with Cl₂ and Ar and ashing. FIG. 13F depicts the final convex lenses, which are in generally a hemispherical shape.

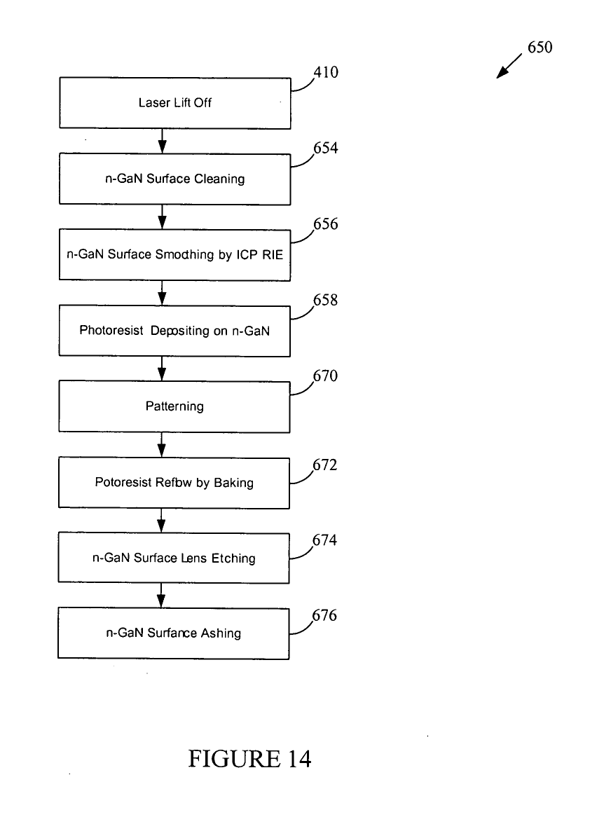

FIG. 14 is a flowchart showing steps for performing the micro-lens formation, according to an embodiment of the invention. The operations performed in steps 654-676 are an expansion of those performed in step 412 in FIG. 4 for this exemplary embodiment of the invention.

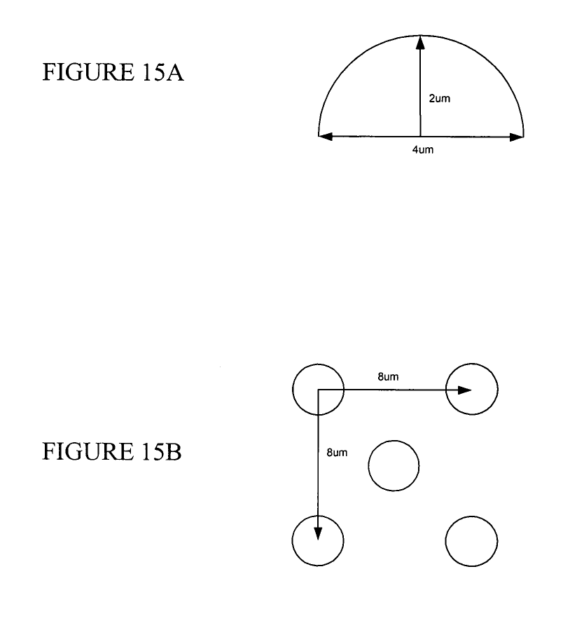

FIGS. 15A-B depict exemplary size and placement of the micro-lenses, according to an embodiment of the invention. The figures show lenses approximately 4 μm in diameter and at approximately 8 μm patterns.

C. Macro-Lens Formation

A macro-lens can further be formed over the semiconductor devices to further enhance the beam profile. In the invention, the improvement in beam profile refers to the chip-level angle of light output. A conventional vertical LED having an opaque substrate generally produces light in a narrow pencil beam because once the vertical LED is packaged with a reflective lead frame there is no reflection from the reflector. As a result, the beam profile is smaller since only surface emitted beams contribute the beam profile. On the other hand, convention lateral LEDs having transparent substrate have often benefit from a lead frame reflector to make a broader beam profile. This broad beam profile is particularly important for backlight applications for LCD monitors. In order to create uniform beam profile and beam intensity, increasing viewing angle of the light source is important.

In addition to this, there is high demand to make a thinner backlight unit as the mobile display equipment tends to smaller and thinner. Therefore, fabricating a thinner back light is one of the goals for LCD panel manufacturers. While it is possible to make a broader beam profile using a lens in the package level, however, it is not practical to make thinner light source for the thin back light unit.

One way to solve this problem associated with vertical LEDs having an opaque substrate is by employing a chip level macro-lens. The macro-lens can be used with or without forming an undulated surface over light emitting layer (e.g. a micro-lens as described above). When used in combination with the micro-lens, the result is a wide beam profile. Even when used alone, the macro-lens results in a wide chip-level viewing angle. The main concept and process of macro-lens formation is similar to the formation of the micro-lens. However, a difference of the macro-lens formation is to use lens material having a desired reflective index to form a macro-lens system on the LED device, while the micro-lens uses GaN material to create a higher light extraction from the semiconductor device.

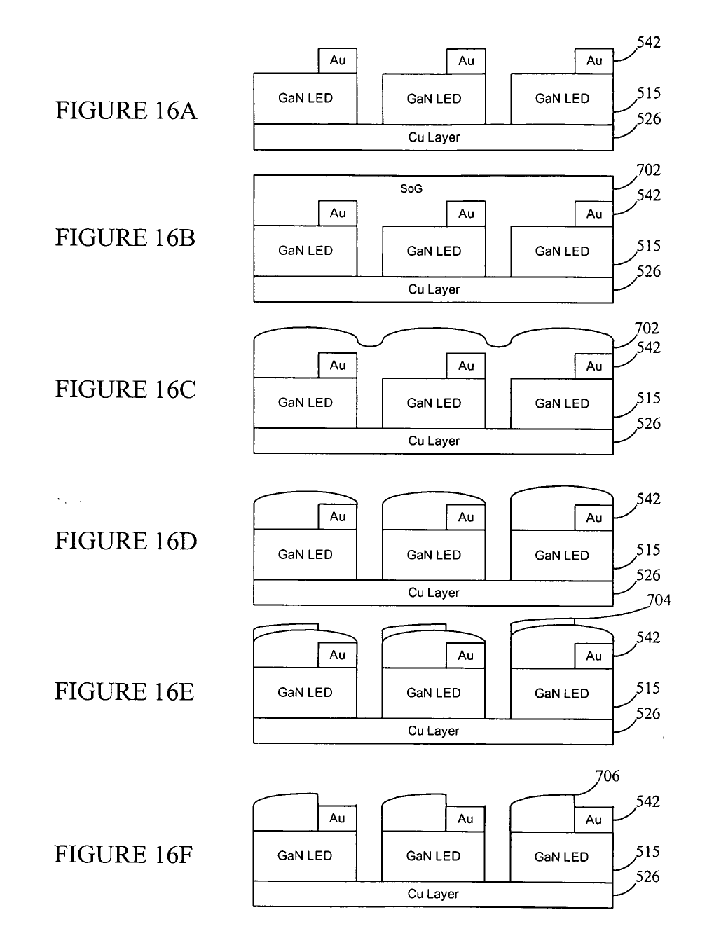

FIGS. 16A-F depict a method of forming macro-lenses, according to an embodiment of the invention. FIG. 16A depicts a light emitting layer 515 (GaN) that may include an undulated surface, or may not include an undulated surface. FIG. 16B depicts depositing a spin-on-glass layer 702 (SoG). In one aspect, the SoG thickness is over 30 μm to form a concave type macro-lens. FIG. 16C depicts SoG reflow by baking. SoG reflow is useful to forming a convex type macro-lens. This can be done by baking SoG at about 110 Celsius for 1.5 minutes. FIG. 16D depicts etching by ICPRIE, which is performed to obtain highly anisotropic etching characteristics. This can be done with high concentration (>90%) of Cl₂ gas in the mixture of Cl₂ and BCl₃ gases. In order to obtain the convex type lens morphology, the bias voltage is also maintained high compared to normal etching conditions. FIG. 16E depicts depositing photoresist 704 over the devices and patterning the photoresist to permit etching above contacts 542. FIG. 16F depicts etching to open the contact 542 and removing the residual photoresist, resulting in finished devices having a macro-lens.

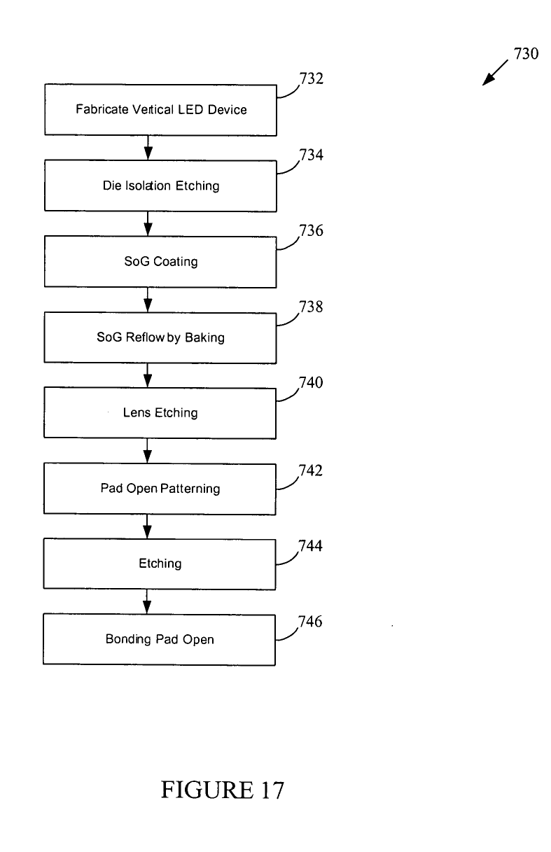

FIG. 17 is a flowchart showing steps for performing the macro-lens formation, according to an embodiment of the invention.

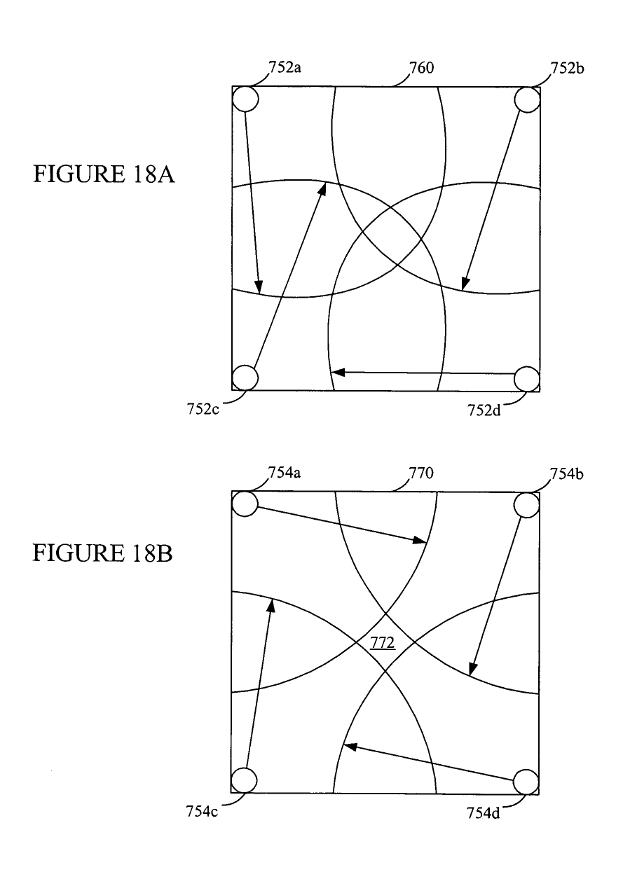

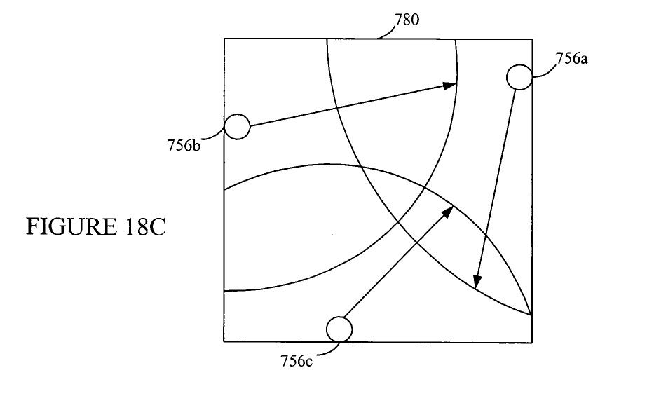

FIGS. 18A-C depict exemplary beam profiles for backlighting LCD displays, according to embodiments of the invention. FIG. 18A depicts a technique using 4 wide angle LEDs 752a-752d. Each of the LEDs included a beam pattern shown with an arrow for each LED. Note that the pattern 770 includes full coverage over the display. However, if narrow beam LEDs are used, FIG. 18B depicts a black spot dark area 772 where insufficient backlight is provided to view the display. The invention provides a solution to the narrow beam problem by incorporating the lenses to widen the beam dispersion, resulting in a wide chip-level viewing angle. In one aspect, shown in FIG. 18C, the light can be sufficiently wide to reduce the number of LEDs required to provide backlight. FIG. 18C depicts 3 LEDs that provide light beam profiles sufficient to provide full backlight. Advantages to using fewer LEDs are less expense, less heat generation and less battery consumption on portable battery-driven products.

D. Packaging

As described above, final product thickness of the LED back light unit can be further reduced using solder bonding technique. Traditionally, wire bonding techniques are used to package the chip device. However, in order to reduce final packaged device thickness, wire bonding has significant vertical space requirements and is not practical for backlighting applications since there is often a limited height requirement in such applications. Therefore, it is beneficial to use a solder bonding technique to reduce final packaged device thickness, according to an embodiment of the invention.

However, such a solder bonding method is not practical for a conventional vertical LED device having a contact pad located in the center of the device since a lead frame required to make contact with the center would block the surface emitting beam. Therefore, one aspect of the invention is to provide a solder bonding method for the novel device having contact pad in the corner as in the case of this invention embodiment (see FIG. 11B).

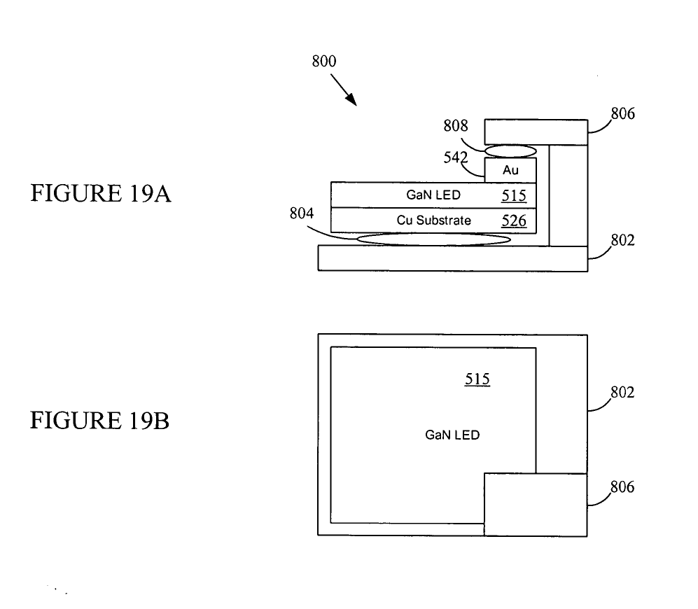

FIGS. 19A-B depict a method of packaging semiconductor devices, according to an embodiment of the invention. FIG. 19A is a side view of a device in a package 800. The package includes a lower lead frame 802 that contacts the device via solder bump 804. An upper lead frame 806 contacts the device via solder bump 808. Contact with the semiconductor device is maintained between the upper lead frame and lower lead frame. In one aspect, contact is formed by one or more of pressure, heat, and vibration between the upper lead frame and lower lead frame.

FIG. 19B is a top view of the device package 800 showing that a significant portion of the device is able to disperse light onto a target area. While the device can be constructed with or without the micro-lenses and macro-lens techniques describe above, the package is shown to permit a great deal of wide angle of light beam to be dispersed on a target area.

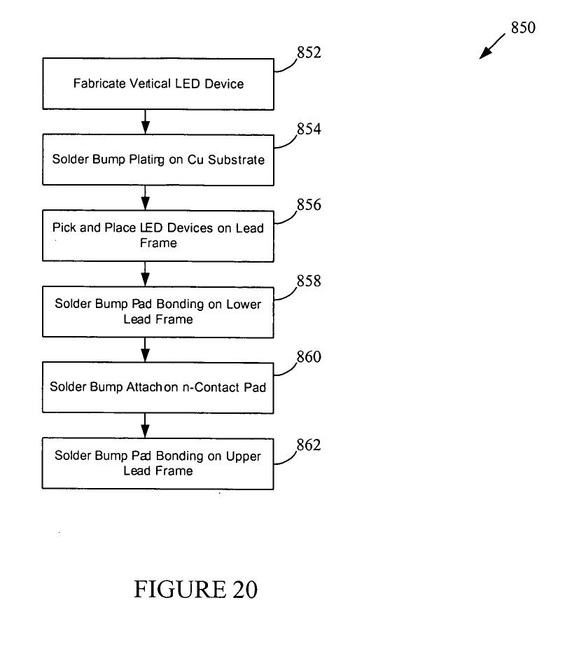

FIG. 20 is a flowchart showing steps for performing the packaging.

Advantages of the packaging include simplified and more reliable device packaging process, no wire bonding or bump pad bonding, reduction in package cost. While this exemplary packaging technique is depicted, other packaging technique can be used in the invention.

E. Conclusion

Advantages and exemplary embodiments of the invention have been disclosed and described herein. Accordingly, having disclosed exemplary embodiments and the best mode, modifications and variations may be made to the disclosed embodiments while remaining within the subject and spirit of the invention as defined by the following claims.

1. A method of fabricating light emitting semiconductor devices, comprising the steps of:
forming a light emitting layer; and
forming an undulated surface over the light emitting layer to improve light output beam profile.

2. The method of claim 1, wherein the step of forming an undulated surface includes the step of forming a plurality of micro-lenses including the steps of:
forming a mask over the semiconductor structure;
removing a portion of the mask resulting in a plurality of substantially circular masks on the surface of the semiconductor structure;
shaping a mask top surface having a certain curvature by mask reflow;
etching the semiconductor structure; and
removing residual mask.

3. The method of claim 2, wherein the light emitting layer is constructed of n-GaN thicker than 2 μm and the micro-lenses are formed on the light emitting layer.

4. The method of claim 3, wherein prior to the forming step, surface smoothening is performed using ICPRIE to create low n-type metal contacts using 100% BCl₃ gas.

5. The method of claim 2, wherein the forming step includes the step of forming a photoresist mask over the semiconductor structure and the shaping step includes the step of photoresist mask reflow to form a substantially hemispherical shape by baking the photoresist mask at about 110 Celsius for about 1.5 minutes.

6. The method of claim 2, wherein the etching is performed to obtain highly anisotropic etching characteristics with a high concentration (>90%) of Cl₂ gas in a mixture of Cl₂ and BCl₃ gases; and in order to obtain a hemispherical lens shape morphology, a high bias voltage is maintained.

7. The method of claim 2, wherein the micro-lenses are approximately 4 μm in diameter and at approximately 8 μm patterns.

8. The method of claim 2, further comprising the step of forming a contact pad over the semiconductor structure in a corner location of the device.

9. The method of claim 1, further comprising the steps of:
forming a macro-lens over the undulated surface of each of the semiconductor devices.

10. The method of claim 1, further comprising the steps of:
forming a contact pad over the semiconductor structure to contact with the light emitting layer; and
packaging each of the semiconductor devices in a package including an upper lead frame and lower lead frame, wherein contact with the semiconductor device is maintained between the upper lead frame and lower lead frame.

11. A method of fabricating light emitting semiconductor devices, comprising the steps of:
forming a light emitting layer; and
forming a macro-lens over the surface of each of the semiconductor devices to improve light output beam profile.

12. The method of claim 11, wherein the step of forming a macro-lens over the surface of each of the semiconductor devices includes the steps of.
depositing a spin on glass (SoG) layer over the semiconductor devices; and
etching the SoG layer to form the macro-lens over the surface of each of the semiconductor devices.

13. The method of claim 11, further comprising the steps of:
forming a contact pad over the semiconductor structure to contact with the light emitting layer; and
packaging each of the semiconductor devices in a package including an upper lead frame and lower lead frame, wherein contact with the semiconductor device is maintained between the upper lead frame and lower lead frame.

14. A method of fabricating light emitting semiconductor devices, comprising the steps of:
forming a light emitting layer;
forming a contact pad over the semiconductor structure to contact with the light emitting layer; and
packaging each of the semiconductor devices in a package including an upper lead frame and lower lead frame, wherein contact with the semiconductor device is maintained between the upper lead frame and lower lead frame.

15. The method of claim 14, further comprising the step of forming a contact pad over the semiconductor structure in a corner location of the device.

16. A light emitting semiconductor device, comprising:
a light emitting layer; and
an undulated surface over the light emitting layer to improve light output beam profile.

17. The light emitting semiconductor device of claim 16, wherein the undulated surface includes a plurality of micro-lenses.

18. The light emitting semiconductor device of claim 17, wherein the light emitting layer is constructed of n-GaN thicker than 2 μm and the micro-lenses are formed on the light emitting layer.

19. The light emitting semiconductor device of claim 18, further comprising low n-type metal contacts.

20. The light emitting semiconductor device of claim 17, wherein the micro-lenses are a substantially hemispherical shape.

21. The light emitting semiconductor device of claim 18, wherein the micro-lenses are a substantially hemispherical shape.

22. The light emitting semiconductor device of claim 17, wherein the micro-lenses are approximately 4 μm in diameter and at approximately 8 μm patterns.

23. The light emitting semiconductor device of claim 17, further comprising a contact pad over the semiconductor structure in a corner location of the device.

24. The light emitting semiconductor device of claim 16, further comprising a macro-lens over the undulated surface of the semiconductor device.

25. The light emitting semiconductor device of claim 16, further comprising:
a contact pad over the semiconductor structure to contact with the light emitting layer; and
a package including an upper lead frame and lower lead frame, wherein contact with the semiconductor device is maintained between the upper lead frame and lower lead frame.

26. A light emitting semiconductor device, comprising:
a light emitting layer; and
a macro-lens over the surface of the semiconductor device to improve light output beam profile.

27. The light emitting semiconductor device of claim 26, wherein the macro-lens comprises spin on glass (SoG).

28. The light emitting semiconductor device of claim 26, further comprising:
a contact pad over the semiconductor structure to contact with the light emitting layer; and
a package including an upper lead frame and lower lead frame, wherein contact with the semiconductor device is maintained between the upper lead frame and lower lead frame.

29. A light emitting semiconductor device, comprising:
a light emitting layer;
a contact pad over the semiconductor structure to contact with the light emitting layer; and
a package including an upper lead frame and lower lead frame, wherein contact with the semiconductor device is maintained between the upper lead frame and lower lead frame.

30. The light emitting semiconductor device of claim 29, wherein the contact pad over the semiconductor structure is positioned in a corner location of the device.

31. A light emitting semiconductor device manufactured according to the method of claim 1.
